(19) United States
(12) Patent Application Publication
(10) Pub. No.: US 2006/0278519 A1
(43) Pub. Date: Dec. 14, 2006

(54) Adaptable fixation for cylindrical magnetrons

(76) Inventors: Leszek Malaszewski, Walnut Creek, CA (US); Olaf Gert Gawer, Dresden (DE)

Correspondence Address: PARSONS HSUE & DE RUNTZ LLP, 595 MARKET STREET, SUITE 1900, SAN FRANCISCO, CA, 94105, US

(21) Appl. No.: 11/150,337

(22) Filed: Jun. 10, 2005

(51) Int. Cl. C23C 14/32; C23C 14/00

(52) U.S. Cl. 204/192.1; 204/298.16

(57) ABSTRACT

A circular groove formed in the end of a cylindrical target allows a retaining ring and flange ring to be attached to the target. The target can then be clamped to an endblock. Targets configured for screw-on affixation may be converted for clamped affixation in this way. Endblocks configured for screw-on targets are modified to clamp targets by modifying or replacing spindles and adding clamp rings.

### BACKGROUND

This invention relates to cylindrical magnetron sputtering systems. In particular, this invention relates to the coupling of cylindrical targets to endblocks of cylindrical magnetron systems.

Large substrates, such as sheets of architectural glass may be coated with a variety of materials to modify their optical, thermal and aesthetic qualities. For example, an optical coating may be used to reduce the transmission of visible light (a solar control coating), decrease absorption of energy (a low-emissivity coating), or reduce reflectance (an anti-reflective coating). U.S. Pat. No. 6,589,657 entitled “Anti-Reflection Coatings and Associated Methods” and U.S. Published Patent Application No. 2003/0043464 entitled “Optical Coatings and Associated Methods,” both of which are hereby incorporated by reference in their entirety, describe the formation and use of coatings that affect the optical characteristics of a glass substrate.

Coating large substrates such as architectural glass presents particular problems. Architectural glass is generally produced in large sheets measuring up to 3.2 meters by 6 meters (126 inches by 236 inches). Such sheets are difficult to handle. Coating systems (coaters) generally consist of multiple process modules (chambers) arranged in series so that a substrate can pass from one process module to the next. Substrates are generally moved by rollers that also support the substrates. The substrate generally enters the coater at one end and passes through multiple process modules where it is coated with different materials. Substrates may be oriented so that they are horizontal and are moved along a horizontal plane, though in other systems substrates are arranged in vertical or near vertical orientations. FIG. 1 shows an example of a coater 100 having multiple process modules 102a-102e arranged so that a substrate 104 passes sequentially from one process module to the next. Within a process module there may be multiple compartments or bays carrying out different processes.

One common coating process is sputtering of a target material from a cylindrical target onto the substrate as the substrate moves past the target. Sputtering generally takes place in a vacuum environment. Coating large substrates such as large sheets of glass using cylindrical magnetrons presents particular problems. The large substrates must be moved past the target under vacuum while the target rotates and while target material is sputtered. This requires maintaining a vacuum environment for sputtering but also enabling moving parts within the vacuum environment. In addition, a high power electrical supply is needed for sputtering, and cooling water is needed to prevent excessive heating. Systems and methods for depositing materials in this way are described in U.S. Pat. No. 6,736,948 entitled “Cylindrical AC/DC Magnetron with Compliant Drive System and Improved Electrical and Thermal Isolation,” which patent is hereby incorporated by reference in its entirety.

FIG. 2 is a cross-sectional view of a compartment of process module 102a of FIG. 1. FIG. 2 shows substrate 104 supported by a roller 206 as it is moved through process module 102a in a direction perpendicular to the plane of the cross-section. Rollers generally support and move the substrate through the coater. Above substrate 104 is a target 208. Target 208 is cylindrical in shape and has target material on its outer (cylindrical) surface. The target material is sputtered from target 208 and some of the sputtered material is deposited on substrate 104. As the target material is sputtered, target 208 is rotated so that the target material is eroded evenly around target 208.

Endblocks 210, 212 support target 208 at either end. Endblocks 210, 212 also support an array of permanent magnets inside target 208. Endblocks 210, 212 also provide the rotational force to rotate target 208 and provide the electrical power to target 208 that causes sputtering. In addition, endblocks 210, 212 provide cooling water that flows through the interior of target 208 to prevent overheating from high power used to sputter the target material. A detailed description of such endblocks is provided in U.S. Pat. No. 6,736,948.

Affixing a target to an endblock presents several problems. The seal between the target and the endblock must be watertight because cooling water flows through the inside of the target and can cause damage if it leaks. The seal must withstand a range of temperatures without failure because the target becomes hot during use. The affixation must be strong enough to support the target and to transmit rotational force used to turn the target. The affixation must allow attachment and detachment of targets from the endblock without unreasonable difficulty and be electrically conductive. In a manufacturing environment, targets must be changed periodically as the target material erodes. To minimize downtime, it should be possible to change targets rapidly. Also, it is desirable to be able to change targets without special tools or special training. Various systems for affixing targets to endblocks are used.

In some systems, targets are affixed by a threaded coupling. FIG. 3 shows such a screw-on coupling between a spindle 314 and a target 316 in cross-section. Target 316 includes a target tube 318 with target material 320 overlying a portion of the outer surface of target tube 318. The outer surface of target 316 has a threaded portion 322 near the end. Spindle 314 is encircled by a spindle ring 324 that has a threaded inner surface to allow coupling to threaded portion 322 of target 316. A spring 326 is inserted between spindle ring 324 and target 316 so that it engages the threaded portions of both spindle ring 324 and target 316. As spindle ring 324 and target 316 are screwed together, spindle 314 and target 316 are forced together, compressing an o-ring 328 and forming a seal. An example of this type of system is given in U.S. Pat. No. 5,591,314 (Morgan Patent).

An alternative screw-on affixing system uses a ledge formed on a target to engage a collar. The collar has a threaded inner surface to allow it to engage a retainer ring that is placed behind a spindle. By screwing the retainer ring and collar together, the spindle and target are forced together, compressing an o-ring and forming a seal. An example of this type of system is given in U.S. Pat. No. 6,375,815 (Lynn Patent).

The threaded couplings used in these examples have several drawbacks. The threaded surfaces require precision machining which can be costly and difficult. In particular, where the target is of a material that is difficult to machine, forming a threaded surface may be expensive. Also, threaded couplings do not always give an even seal between the target and spindle. If the o-ring is not evenly compressed, leaks may occur at some points even though the coupling appears to be tight. Misalignment may also occur between the spindle and target with this system so that the target rotates about an axis that is not concentric with the target axis. Such misalignment produces a poor seal. One example of a target using a threaded coupling is commonly sold as a Quick Change Target (QCT).

Improved affixation systems are described in US Patent Application Publication Nos. 2004/0163943 and 2005/0051422, both entitled “Cylindrical Magnetron with Self Cleaning Target,” which applications are hereby incorporated by reference in their entirety. These systems use clamps that do not require a threaded surface on the target or a threaded ring. This makes construction of the target simpler and cheaper, allows easier changing of targets and provides a better seal by more evenly compressing the o-ring between the spindle and target. Concentricity of the target and spindle is also improved. A commercially successful endblock that includes a clamped system of affixation is the VAC-MAG™ endblock from Vacuum Coating Technologies Inc.

While a system using a clamp instead of a threaded coupling has many advantages, many coaters are still in use that have threaded couplings. Also, many targets are sold that have threaded portions for affixation but are not configured for clamping. Some users that have installed newer technology using clamping, still have coaters that require threaded targets and may have a stock of threaded targets. Therefore, there is a need for a method of adapting threaded targets to allow them to be used in a clamped configuration. There is also a need for a method of adapting an endblock that is configured for threaded targets so that targets can be clamped to such endblocks. There is also a need for suitable apparatus for such adaptation.

### SUMMARY

A target that has a threaded portion for affixation to a similarly threaded endblock component is modified so that it can be clamped. The modification includes forming a circular groove near the end of the target and inserting a retaining ring in the groove to hold a flange ring that encircles the end of the target. The flange ring is sized so that a clamp ring can fit over it and over an endblock spindle to clamp the target to the spindle. A target may be modified in the field in this way so that it can be used with an endblock configured for clamping. The flange ring and retainer ring can be removed and the target can still be affixed using the threaded portion. The circular groove does not interfere with use of the threaded system of affixation. Targets that do not have a threaded portion may also be affixed in this way. In some cases, different targets require different o-ring locations in the spindle they are affixed to, so some modification of a spindle may be needed.

An endblock that is configured for threaded targets can be adapted for a clamp-style affixation by removing a threaded spindle ring and adding an adaptor flange. The adaptor flange may simply be bolted to the existing flange with an o-ring sealing between the adaptor flange and the spindle. This is generally all that is required to adapt a water endblock spindle. The adaptor flange has a circular groove to hold an o-ring that seals against a target. A clamp ring is placed about the flange and a target flange at the end of the target.

In some cases an endblock may require more modification to allow clamping of targets. Some drive endblocks have spindles that can be removed by simply sliding them out when there is no target present. Such spindles are easily replaced or removed for modification. A spindle may be modified to have a larger overall diameter and a new o-ring position corresponding to the target to be used.

### BRIEF DESCRIPTION OF THE DRAWINGS

FIG. 1 shows a coater of the prior art having multiple process modules through which a substrate passes during processing.

FIG. 2 is a cross-sectional view of a compartment within a process module of FIG. 1, showing a cylindrical magnetron sputtering system of the prior art.

FIG. 3 is a cross-sectional view of the affixation of the target to the endblock of FIG. 2, showing the threaded portion of the target and the spindle ring with corresponding threaded inner surface according to the prior art.

FIG. 4 is a cross-sectional view of an affixation of a target to an endblock, using a retaining ring and a flange ring, according to an embodiment of the present invention.

FIG. 5 shows the target of FIG. 4 having a circular groove near the end of the target in addition to the spiral groove.

FIG. 6A shows an exploded view of a target, flange ring, retaining ring and spindle.

FIG. 6B shows a close-up view of an end portion of the target of FIG. 6A in detail.

FIG. 6C shows an end portion of another target that does not have a spiral groove.

FIG. 6D shows an end portion of yet another target that has a chamfered surface.

FIG. 7A shows a close-up view of the retaining ring and circular groove of FIG. 4.

FIG. 7B shows a close-up view of an alternative retaining ring and circular groove.

FIG. 7C shows a close-up view of another alternative retaining ring.

FIG. 8 shows a spindle that is adapted for clamping to a target by the addition of an adaptor flange according to an embodiment of the present invention.

FIG. 9 shows the adaptation of a spindle for clamping to a target by addition of a new portion to a spindle.

FIG. 10A shows the spindle of FIG. 9 in its original state prior to modification.

FIG. 10B shows the spindle of FIG. 9 in an intermediate state during modification.

FIG. 10C shows the spindle of FIG. 9 in the final state, adapted for clamping to a target.

FIG. 12 illustrates the forces exerted by a clamp ring on the flanges encircled by the clamp ring as the clamp ring is tightened.

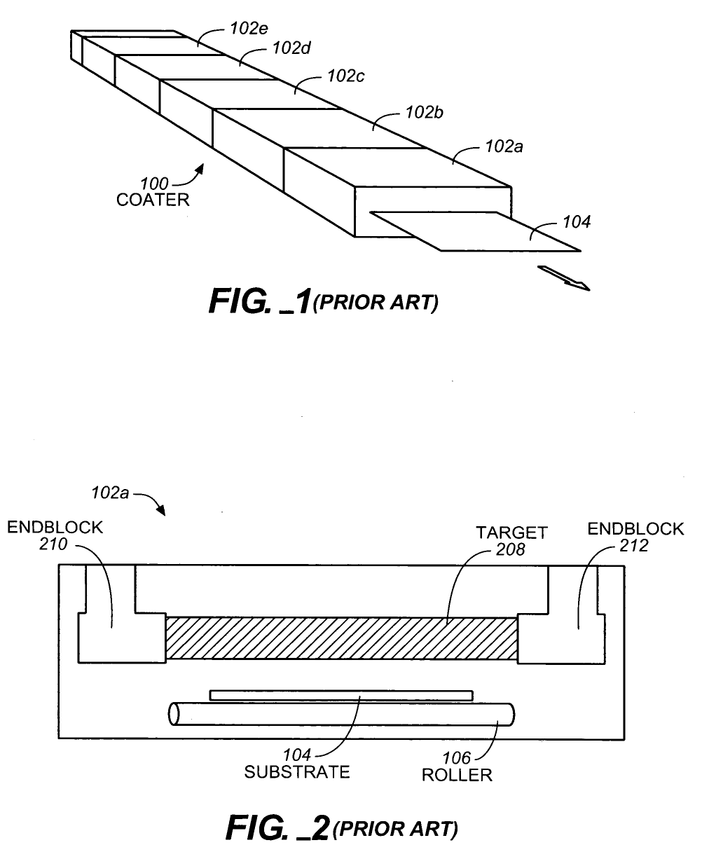

### DESCRIPTION OF EMBODIMENTS SHOWN

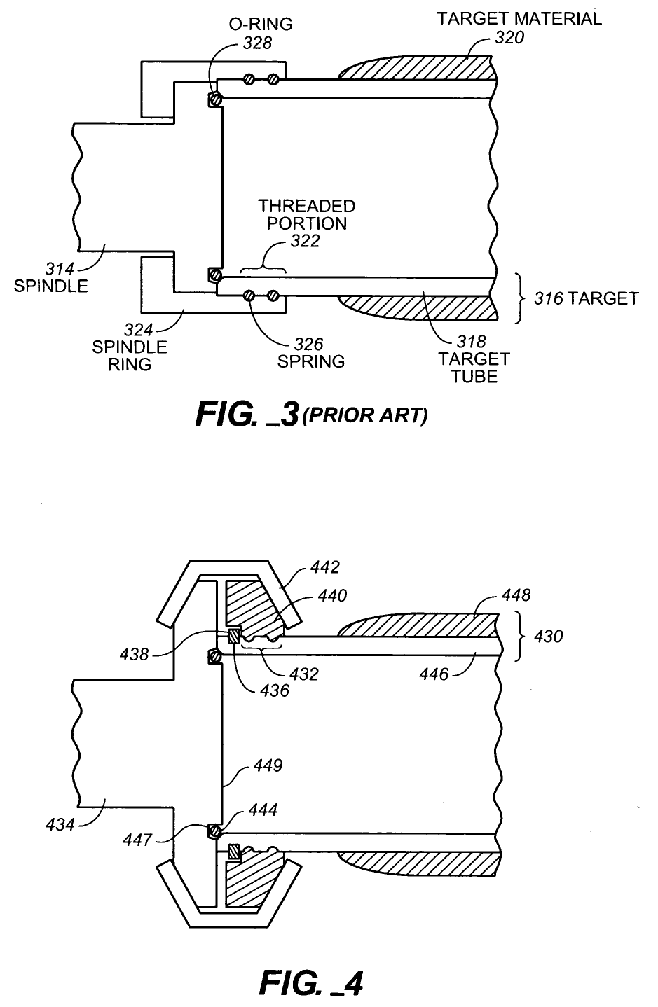

In a first embodiment, a target that has a threaded portion near its end for coupling to an endblock with a corresponding threaded ring is adapted for use in a clamped configuration. FIG. 4 shows a target 430 that has a threaded portion 432 on its outer surface. Target 430 is clamped to a spindle 434 using an adapter kit according to an embodiment of the present invention. A circular, circumferential groove 436 is located between threaded portion 432 of target 430 and the end of target 430. Groove 436 may be formed during manufacturing so that target 430 is usable with different affixing systems. Alternatively, groove 436 may be formed on-site, at a facility where the target is used or stored, so that targets can be adapted for different endblocks as needed. A retaining ring 438 in the form of a “C” or other shape is placed in groove 436 so that it encircles target 430. An example of a retaining ring is a split ring that is formed of a single piece of metal in a ring shape, but with a split between ends to allow the split ring to be expanded to move it into place. A flange ring 440 extends around target 430. The location of flange ring 440 is established by retaining ring 438. A clamp ring 442 extends about spindle 434 and flange ring 440 and forces flange ring 440 and spindle 434 together. Because retaining ring 438 holds flange ring 440 from moving along the axis of target 430, target 430 is forced against spindle 434 as clamp ring 422 is tightened. An o-ring 444 is located in a circular groove 446 formed in a front surface 448 of spindle 434 that faces target 430. o-ring 444 lies where target 430 meets spindle 434 so that as target 430 and spindle 434 are forced together, o-ring 444 is compressed and forms a seal between target 430 and spindle 434. The force between target 430 and spindle 434 is evenly distributed around o-ring 444 so that a good seal is formed. Without flange ring 440 and retaining ring 438, target 430 can be used with a threaded collar as described in the prior art. The addition of circular groove 436 does not prevent use of the threaded portion 432 in a threaded affixation system. It should be noted that no o-ring is needed and thus no seal is formed between flange ring 440 and spindle 434. There is also no seal needed between the flange ring 440 and target 430 in this configuration. Thus, flange ring 440 and retaining ring 438 do not have to be made to very high precision and do not require highly polished sealing surfaces.

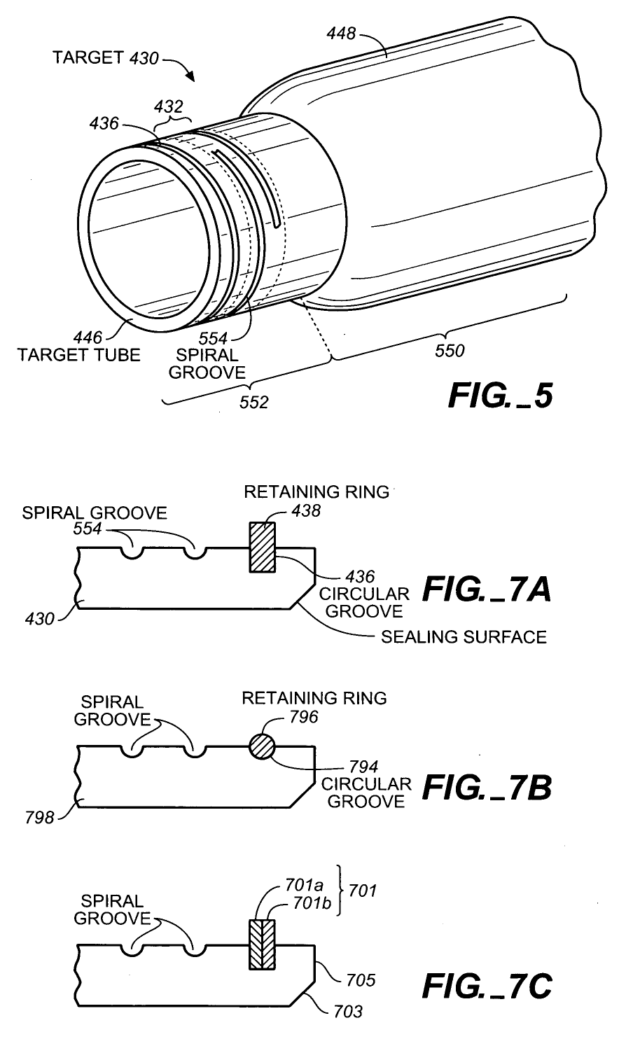

FIG. 5 shows the end of target 430, with a portion 550 of target tube 446 covered by target material 448 and an exposed portion 552 of target tube 446 that is not covered by target material 448. A spiral groove 554 is located in exposed portion 552 of the target tube 446 forming threaded portion 432. While spiral groove 554 extends only slightly more than 360 degrees about target tube 446, other configurations are possible. A circular groove 556 is located between spiral groove 554 and the end of target 430. It has been found that targets having threaded portions formed according to prior art systems of affixation leave sufficient space between the threaded portion and the end of the target tube to allow a groove to be machined. This portion of the target surface is otherwise unused and machining a groove in this region does not adversely affect the target. Circular groove 556 of this example extends completely around the target (360 degrees) at a fixed distance from the end of target 430. A flange ring and a retaining ring can easily be attached to, or detached from target 430. Thus, the same target can be adapted for use with whichever type of endblock is required.

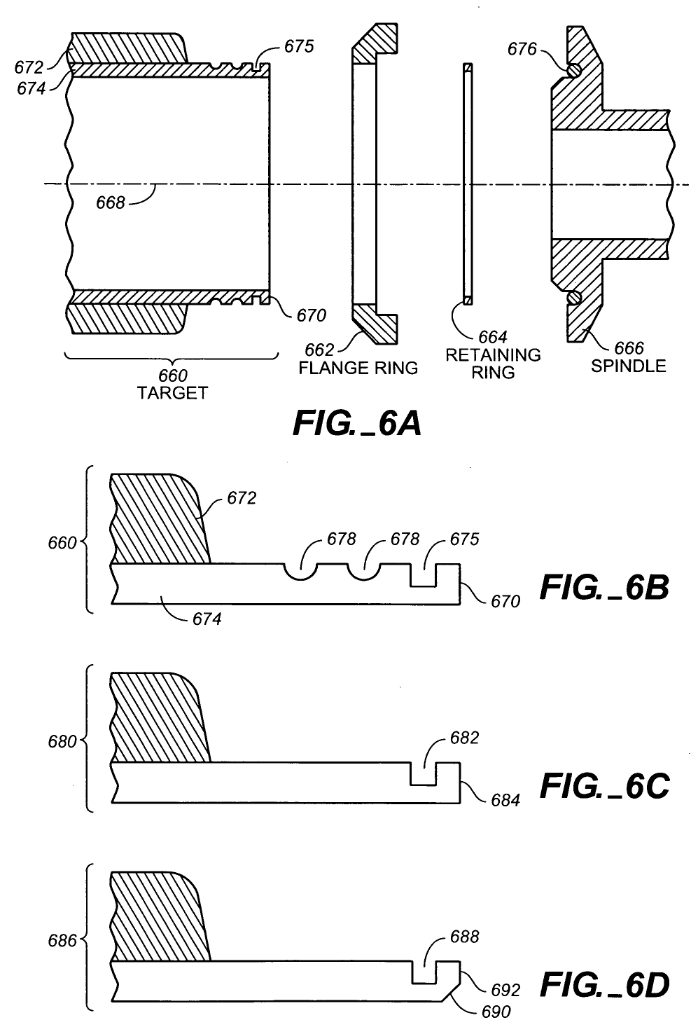

FIG. 6A shows an exploded diagram of a target 660, flange ring 662, retaining ring 664 and spindle 666 separated along the axis 668 of target 660. Flange ring 662 and retaining ring 664 are removable and are not permanently attached to target 660. Conversion to a clamped configuration may be done rapidly and without specialized knowledge or equipment. Flange ring 662 is slipped over target 660 and pushed away from the end 670 of target 660. Typically, flange ring 662 fits over target 660 at this point with some small clearance. However, flange ring 662 may be prevented from moving further along target 660 by target material 672 as shown. Target 660 has a target tube 674 (backing tube) with target material 672 on a portion of its outer surface. However, other target structures are also used. For example, an entire target may be formed of target material. Collars of different materials may be added near the ends of the target. When flange ring 662 is pushed away from end 670 of the target 660, groove 674 is exposed and retaining ring 664 may be inserted in groove 674. Retaining ring 664 is made of a spring type material such as steel or other metal. Retaining ring 664 extends around target 660 and stays in place because it acts as a spring to hold target 660. A retaining ring may extend a full 360 degrees or close to 360 degrees. A retaining ring may extend more than 360 degrees so that end portions of the retaining ring overlap each other. Once retaining ring 664 is in position, flange ring 662 can be moved towards the end 670 of target 660 where it is stopped by retaining ring 664. Target 660 is moved into position against spindle 666 so that end 670 of target 660 aligns with o-ring 676. A clamp ring (clamp) is then placed around flange ring 662 and spindle 666. The clamp ring is tightened so that flange ring 662 (and target) are forced towards spindle 666, thus compressing o-ring 676 and sealing the gap between target 660 and spindle 666. While this system is used to adapt a threaded target, it may also be used with other targets that do not have threaded portions. This method of affixing a target to an endblock can be used on targets designed for other affixation systems or can be used with targets that are specifically designed to use only this method of affixation.

FIG. 6B shows a close up view of an end portion of target 660 of FIG. 6A. Target 660 has spiral groove 678 for threaded coupling to an endblock. Circular groove 674 is located between spiral groove 678 and end 670 of target 660. End 670 of target 660 is a surface that is perpendicular to the axis of target 660. End 670 provides a sealing surface to seal between target 660 and spindle 666. A sealing surface is a surface that is placed in contact with an o-ring or similar seal and against which the o-ring is compressed. Typically, sealing surfaces should be extremely smooth and may be highly polished to achieve the desired smoothness. Target 660 is an example of a target that was originally manufactured for use with a threaded coupling but was later adapted for use with a clamped coupling by forming groove.

FIG. 6C shows an end portion of another target 680 that does not have a spiral groove. Target 680 has a circular groove 682 located near the end of target 680 for holding a retaining ring similarly to target 660. The end of target 680 has a surface 684 that is perpendicular to the axis of target 680. Target 680 is an example of a target that was not manufactured for use with threaded couplings and therefore has no spiral groove. Such targets may be designed to be coupled by clamping, or may be designed for some other coupling system and later modified for clamping.

FIG. 6D shows an end portion of yet another target 686. Target 686 has a circular groove 688 but does not have a spiral groove or threaded portion. Target 686 has a chamfered end so that a chamfered surface 690 is provided that extends around the inside opening of target 686. Chamfered surface 690 may form a sealing surface that seals with a spindle. Chamfered surface 690 is less exposed than end surfaces that are not chamfered (such as surface 684 of target 680) and chamfered surface 690 is thus less vulnerable to damage when target 686 is handled. The dimensions and finish of the chamfered surface 690 may be determined according to the spindle that is used. Where a chamfered surface is provided, another surface may still be used to seal. Thus either surface 690 or surface 692 of target 686 may be a sealing surface. Surface 690 and surface 692 may be used as alternative sealing surfaces depending on the spindle to which target 686 is attached. Other surfaces of targets such as target 686 may also be used as sealing surfaces.

As described in US Patent Application No. 2005/0051422, a collar may be used as part of a cylindrical target to improve target life. In one example, a flange ring may be a collar covering part of the target. In another example, a flange ring may be a special part of the target or/and integral part of the target for coating process purposes. In general, the affixation method used in the above example is usable with a wide range of cylindrical targets including those with collars and targets that already have other features for affixation.

FIG. 7A shows a close-up view of the retaining ring 438 and target 430 of FIGS. 4 and 5 in cross-section. Retaining ring 438 remains within groove 436 because it has an inner diameter that is less than the diameter of target 430 at that point. The outer diameter of the retaining ring 438 is greater than the diameter of target 430 at that point so that retaining ring 438 extends beyond the surface of target 430 to stop a flange ring from passing this point.

FIG. 7B shows an alternative groove and retaining ring design. Here the circular groove 794 is semi-circular in cross-section and retaining ring 796 is circular in cross-section. This design reduces stress in target tube 798 caused by formation of groove 794. Typically forming a circular groove does not require machining with less than 10 mils (0.01 inch) precision. Thus, forming the groove is not prohibitively expensive or difficult.

FIG. 7C shows another alternative retaining ring design. Retaining ring 701 has two portions 701a and 701b, shown in cross section. This is an example of a retaining ring that extends more than 360 degrees so that ends of the retaining ring overlap each other. The view shown is a cross section of the overlapping portions 701a, 701b. Other designs may also be used to provide a retaining ring that is captured along the axis of the target and presents a barrier to the flange ring. While FIGS. 7A, 7B and 7C show targets having chamfered ends, various end surfaces may be combined with the different retaining rings shown.

FIGS. 4-7 show conversion of threaded targets (such as a target configured for QCT affixation) for affixation to endblocks that use clamping (such as a VAC-MAG™ endblock). In some cases an endblock may require some modification depending on the type of target affixed. For example, even though the targets shown in FIGS. 4-7 are modified so that they can be clamped, these targets may have sealing surfaces that are not at the locations corresponding to the o-rings in the endblock to which it is to be affixed. FIG. 7C shows the locations of the sealing surfaces including chamfered surface 703 and end surface 705. If the target's sealing surface does not correspond to the o-ring location, an o-ring groove must be formed in the endblock spindle at the corresponding location so that an o-ring can be provided there and a seal can be made. A spindle may be adapted by machining such a groove as required, or a replacement spindle may be inserted that has the desired groove location. An adaptable spindle has grooves for o-rings at locations for different targets. For example, an inner circular groove in a spindle may be located to correspond to the sealing surface of a QCT type target, while an outer circular groove in the same spindle is located to correspond to the sealing surface of a VAC-MAG™ target.

The above descriptions relate to a single endblock coupled to a target. However, in most cases, both ends of a target have similar features and both endblocks of a magnetron have a similar coupling component. Therefore, when one end of a target is modified for clamping, usually the other end is also modified in the same way. While it is possible to have one end of a target screwed in place and the other end clamped in place, this is not normally desirable. Similarly, it may be possible to have different affixing configurations on different targets in the same coater; but in general, an entire coater uses a single system of affixation.

An adaptor kit for converting targets as shown in FIGS. 4-7 could include two flange rings and two retainer rings, a flange ring and retainer ring for each end of the target. If grooves are made at each end of the target, this allows the target to be configured for clamping at any time. The target can be reconfigured for threaded affixation by simply removing the retaining rings and sliding off the flange rings.

In another embodiment, an endblock is adapted to work with a different kind of target than it was originally configured for. Because there are many installed endblocks that are configured for threaded targets in the coating industry, it is sometimes desirable to convert such endblocks instead of replacing them. By converting such endblocks to allow clamping of targets instead of screwing targets in place, some of the benefits of clamped targets may be enjoyed without the time and cost of replacing the endblocks.

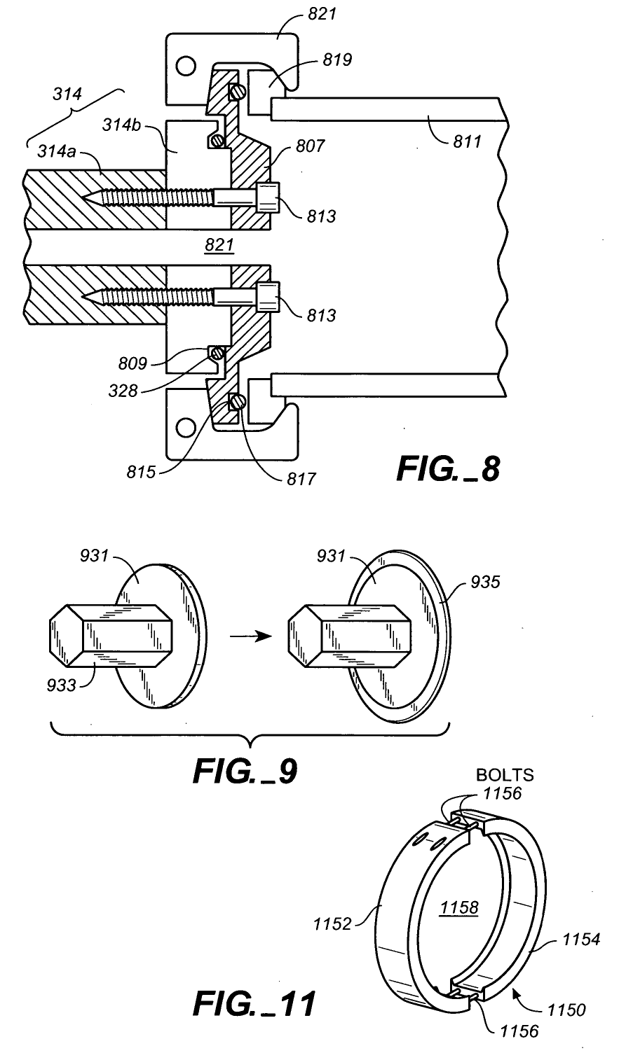

Starting from an endblock with a spindle and threaded spindle ring such as that shown in FIG. 3, the target is removed and then the spindle ring is removed. This may require cutting the spindle ring or partially disassembling the endblock. In some designs, a spindle has an outer portion and an inner portion that are bolted together by bolts that extend parallel to the axis of the spindle. The outer portion and inner portion may be unbolted and separated to allow a spindle ring to be removed. A gasket between the outer portion and the inner portion may then be replaced before bolting the two portions together again. Some of these bolts may be removed and an adaptor flange may then be bolted in place using the holes that previously held the removed bolts. The same bolts may be reused for this purpose or longer bolts may be needed with the adaptor flange. In one example, four out of a total of eight bolts are removed from the spindle, then four bolts are used to hold the adaptor flange to the spindle. FIG. 8 shows an example where the water spindle 314 of FIG. 3 is comprised of an inner portion 314a and an outer portion 314b. Outer portion 314b has an adaptor flange 807 bolted to it. O-ring 328 in circular groove 809 in spindle 314 seals between spindle 314 and adaptor flange 807. Bolts 813 are tightened to sufficiently compress o-ring 328 to provide a good seal. Another circular groove 815 is located in the surface of adaptor flange 807 that faces target 811. Another o-ring 817 is located in groove 815 to seal between adaptor flange 807 and target 811. In this example, target 811 has a target flange 819 to facilitate clamping. A target flange may be welded to the target tube or may be formed integrally with the target tube. In some cases, a target flange is formed in a collar that is made of a low sputtering rate material. A target flange may also be a flange ring held by a retaining ring as previously described. A clamp ring 821 is placed about adaptor flange 807 and target flange 819. As clamp ring 821 is tightened, target flange 819 and adaptor flange 807 are forced together, compressing o-ring 817 and providing a good seal. The compression is more even than in screwed-together assemblies so that leaks are reduced. Also, as clamp ring 821 is tightened, force is applied inwards in a radial direction, forcing target 811 into alignment with spindle 314.

The system shown in FIG. 8 provides a simple conversion from a threaded affixation to a clamped affixation. This conversion can be done in-situ without specialized training or equipment. This allows targets made according to one standard (e.g. VAC-MAG™ compatible targets) to be used with an endblock that was originally built for a different type of target (e.g. QCT compatible targets). The location of the seal between target and flange is different to the original location of the seal between target spindle so that a larger o-ring 817 is needed. FIG. 8 shows an opening 821 in adaptor flange 807 and spindle 314. Opening 821 allows cooling water to flow between spindle 314 and the inside of target 811. The endblock that supplies cooling water generally has a spindle with this type of opening and is called a water endblock. Features in the drawing are not to scale and it will be understood that this embodiment is not limited to the features as shown.

In some examples, it may be possible to attach a flange to spindles of both endblocks holding a target as shown in FIG. 8. However, this is not always possible. There may not be enough room along the axis of the target to allow two such flanges to be inserted. If flanges are added to spindles at both ends, the target may not fit between the flanges for attachment. Also, in some examples, bolts are only present in the spindle of one endblock (the water endblock). To allow a clamped affixation scheme in such situations, a spindle may require replacement or rework to be compatible with a clamp configuration.

FIG. 9 shows a spindle 931 from a drive endblock of the prior art. Such spindles may be used in endblocks similar to that shown in cross-section in FIG. 3. Spindle 931 has an end portion 933 that is hexagonal in shape to allow coupling of a turning force through the endblock to spindle 931 while also allowing spindle 931 freedom of movement along its axis. This allows spindle 931 to be pushed back as a target is inserted and moved inwards towards the target for affixation. Spindle 931 may be replaced with a spindle having an additional portion 935 or the spindle may have the additional portion 935 attached, such as by welding additional portion 935 to spindle 931. Additional portion 935 includes a circular o-ring groove located to seal with a target. As an alternative to modifying an existing spindle, a replacement spindle may be made from scratch with the appropriate dimensions for clamping.

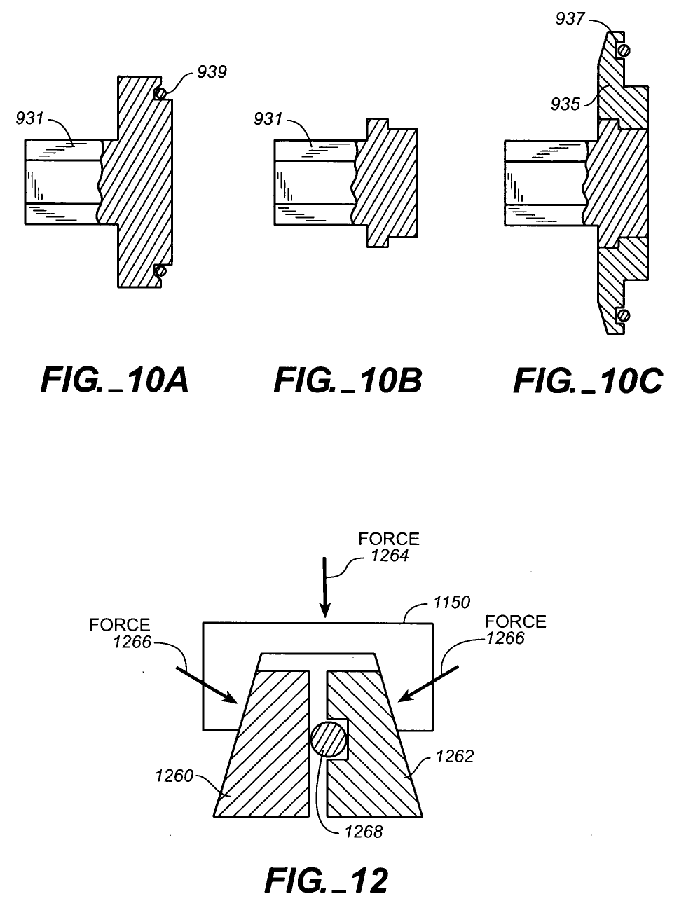

FIGS. 10A-10C show how such a spindle may be modified to be compatible with a clamped configuration. FIG. 10A shows spindle 931 in its original condition before modification. Firstly, an outer portion of spindle 931 is removed as shown in FIG. 10B. Secondly, an additional portion 935 is added as shown in FIG. 10C. Additional portion 935 extends the diameter of spindle 931. Additional portion 935 includes a new circular o-ring groove 937. Circular o-ring groove 937 has a diameter selected to seal against a target flange of a clamped target and thus has a larger diameter than the original o-ring groove 939. In addition, the location of o-ring groove 937 is moved outwards (away from the target) along the axis of the target. This provides some extra room for inserting a target.

Typically, when one endblock is adapted for a new target type, the opposite endblock of the same magnetron is also adapted for the same target type. Where the water endblock is adapted as shown in FIG. 8 by bolting on an adaptor flange, the drive endblock may be modified as shown in FIGS. 10A-10C. The sealing surface of the flange of FIG. 8 is moved slightly inwards along the axis of the target from the prior sealing surface location, while the sealing surface of the modified spindle of FIG. 10 is moved slightly outwards along the axis of the target from the original sealing surface location. Thus, the overall distance between these sealing surfaces can be kept the same or can be modified as required. This means that there is enough space between these surfaces for the target to be inserted.

FIG. 11 shows an example of a clamp ring 1150 that may be used with different embodiments of the present invention. Clamp ring 1150 is made up of two parts 1152, 1154 that are attached together by bolts 1156. With bolts 1156 loosened, clamp ring 1150 has an inner opening 1158 that allows it to pass over a flange or flange ring. When clamp ring 1150 is located over opposing flanges, bolts 1156 are tightened and inner opening 1158 of clamp ring 1150 diminishes. This tends to exert a force inwards in a radial direction on the flanges, forcing the flanges to be concentric. The inner surfaces of clamp ring 1150 are angled and are in contact with correspondingly angled flange surfaces. Thus, as clamp ring 1150 is tightened, the clamp ring 1150 also exerts a force inwards from both sides and forces both flanges together.

FIG. 12 shows a cross-section of clamp ring 1150 forcing two flanges 1260, 1262 together. Force 1264 is shown being exerted in an inward radial direction. This forces flange 1260 and flange 1262 to be concentric. Also, forces 1266 are shown being exerted in an inward direction along the axis of the target. An o-ring 1268 is shown being compressed between flanges 1260, 1262 by forces 1266. A clamp ring used with an adaptor flange or a modified spindle may have a larger diameter than the threaded spindle ring that it replaces. If there is shielding provided around the spindle ring, the shielding may have to be modified to allow for the clamp ring. Typically, shielding is maintained around the clamp ring with a clearance that is less than the dark space distance.

An adaptor kit for converting the two endblocks of a magnetron could include an adaptor flange for the water endblock and a replacement spindle for the drive endblock. Two o-rings could also be included as the o-ring size may be different after the endblock is adapted. Two clamp rings may be included. If there is shielding around the spindle that does not fit around the clamp rings, replacement shielding might also be included that fits around the clamp rings.

While particular embodiments of the present invention and their advantages have been shown and described, it should be understood that various changes, substitutions, and alterations can be made therein without departing from the spirit and scope of the invention as defined by the appended claims.

1. A method of attaching a cylindrical target to an endblock, comprising:
forming a circular groove in an end portion of the target;
positioning a flange ring such that the flange ring encircles the target, the flange ring having an inner diameter that is equal to or greater than the outer diameter of the target;
inserting a retaining ring into the groove, the retaining ring extending about the target; and
subsequently clamping the target to a spindle by placing a clamp ring about the spindle and the flange ring, the flange ring position fixed along the axis of the target by the retaining ring.

2. The method of claim 1 wherein the clamp ring is tightened to exert force both inwards in a radial direction and inwards along the axis of the target.

3. The method of claim 1 wherein the end portion of the target includes a threaded portion and the groove is formed between the threaded portion and the end of the target.

4. The method of claim 1 further comprising similarly attaching the opposite end of the target to another endblock.

5. A cylindrical magnetron sputtering system, comprising:
a cylindrical target having target material on an outer cylindrical surface and having a groove located in an end portion;
a retaining ring in the groove, the retaining ring having an inner diameter that is less than the diameter of the end portion and an outer diameter that is greater than the diameter of the end portion;
a flange ring that encircles the target, the flange ring having an inner diameter that is greater than the outer diameter of the end portion but is less than the outer diameter of the retaining ring so that the flange ring cannot pass over the retaining ring, the flange ring having an outer circumference;
a spindle having an outer circumference; and
a clamp ring that encircles the outer circumference of the flange ring and the outer circumference of the spindle.

6. The cylindrical magnetron sputtering system of claim 5 further comprising an o-ring that seals between the spindle and the target.

7. The cylindrical magnetron sputtering system of claim 5 wherein the target has a threaded portion adjacent to the groove.

8. A cylindrical target assembly for sputtering of target material in a cylindrical magnetron sputtering system, comprising:
a target having target material on an outer cylindrical surface and having a circular groove located in an end portion;
a retaining ring in the groove, the retaining ring having an inner diameter that is less than the diameter of the end portion and an outer diameter that is greater than the diameter of the end portion; and
a flange ring that encircles the target, the flange ring having an inner diameter that is greater than the outer diameter of the end portion but is less than the outer diameter of the retaining ring so that the flange ring cannot pass over the retaining ring.

9. A method of modifying a cylindrical magnetron configured for cylindrical targets having threaded ends to operate with cylindrical targets having flanges, comprising:
removing a threaded collar from an endblock, the threaded collar extending around a spindle, the threaded collar having a threaded inner surface;
attaching an adaptor flange to the spindle, the adaptor flange having an outer circumference;
placing a clamp ring about the outer circumference of the adaptor flange and about a flange attached to a first end of a target; and
tightening the clamp ring to exert force both inwards in a radial direction and inwards along the axis of the target.

10. The method of claim 9 further comprising removing an opposite threaded collar from an opposite endblock, removing an opposite spindle from the opposite endblock, replacing the opposite spindle with an adapted spindle.

11. The method of claim 9 wherein the adapted spindle is made from the opposite spindle but includes additional material not included in the opposite spindle.
